(19) United States
(12) Patent Application Publication
(10) Pub. No.: US 2007/0004242 A1
(43) Pub. Date: Jan. 4, 2007

(54) Socket features for aligning and orienting components

(76) Inventors: Vinayak Pandey, Chandler, AZ (US); Pramod Malatkar, Chandler, AZ (US); Ed Unrein, Surprise, AZ (US)

Correspondence Address: INTEL/BLAKELY, 12400 WILSHIRE BOULEVARD, SEVENTH FLOOR, LOS ANGELES, CA, 90025-1030, US

(21) Appl. No.: 11/173,697

(22) Filed: Jun. 30, 2005

(51) Int. Cl. H05K 1/00

(52) U.S. Cl. 439/70

(57) ABSTRACT

The present invention includes a socket with adjoining features that align, orient, and allow vertical assembly of enabling and non-enabling components. The present invention allows space conservation on the motherboard by stacking components on a socket which may serve as a base feature.

### BACKGROUND

Currently, due to the progressive complexity of computing systems, efforts have been made to decrease the area of components on a motherboard.

Conventionally, the lateral assembly of a CPU package, power connector, voltage regulator and respective heat sinks occupy space in a computing system. Alignment and orientation of these components are constraints to be taken into consideration during assembly.

### BRIEF DESCRIPTION OF THE DRAWINGS

FIG. 1 is an exploded view of a vertical assembly of components aligned and oriented by a socket according to an embodiment of the present invention.

FIG. 2 is a perspective view of a vertical assembly of components facilitated by a socket according to an embodiment of the present invention.

FIGS. 3A-3D are embodiments of the present invention of a socket with wall and pin features to orient and align components.

FIG. 3E is an illustration of a wall with a tapered top portion according to an embodiment of the present invention.

FIG. 3F is a top view of a socket with socket pin features according to an embodiment of the present invention.

FIG. 4 is an illustration of the way a CPU package is aligned and oriented by socket features according to an embodiment of the present invention.

FIG. 5 is an illustration of the way a voltage regulator board with adjoining power connectors are aligned and oriented to a socket according to an embodiment of the present invention.

FIG. 6 is an illustration of the way the power connectors of a voltage regulator align to a socket according to an embodiment of the present invention.

FIG. 7 is a perspective view of a component subassembly prior to being oriented and aligned by a socket according to an embodiment of the present invention.

FIG. 8 is a perspective view of a vertical assembly of components by a socket in a computing system according to an embodiment of the present invention.

### DETAILED DESCRIPTION OF INVENTION

In an embodiment, the present invention may include a socket for an electronic package that serves as a base and enables vertical assembly of components. In an embodiment, the socket features walls and a socket pin set which also provides alignment and orientation. In an embodiment, the socket of the present invention facilitates alignment, orientation, and assembly of an electronic package, voltage regulator, power connectors, and respective heatsinks.

Some embodiments of the present invention may eliminate the need for a separate component for aligning and orienting a power connector with respect to an electronic package. Some embodiment of the present invention may save space on a motherboard by providing for a vertical rather than lateral assembly of components.

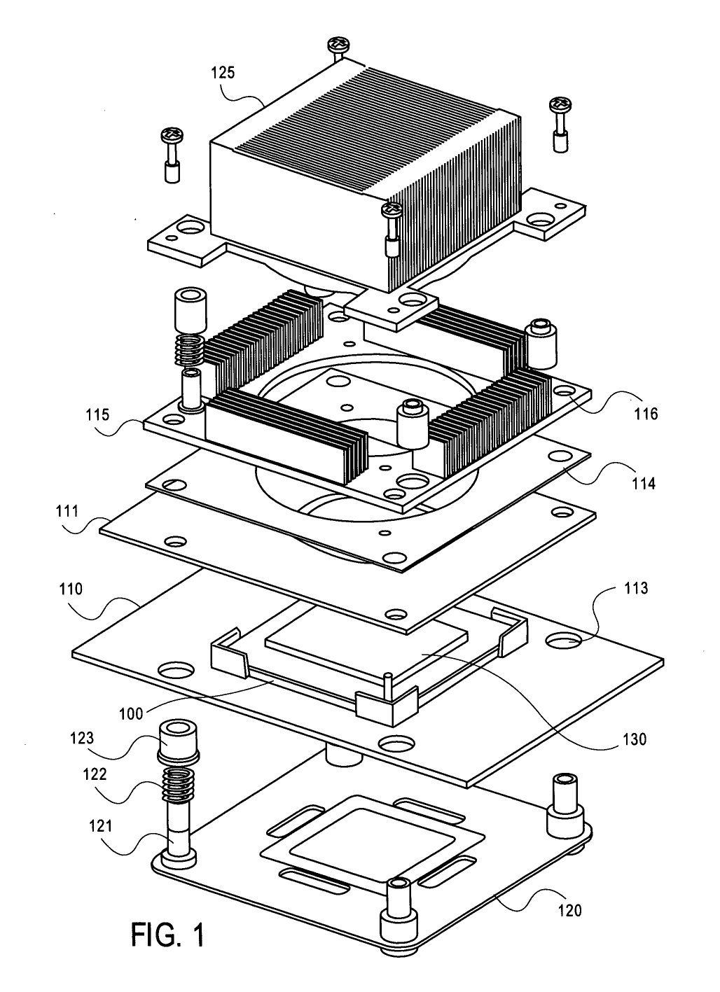

FIG. 1 is an exploded view of a vertical assembly of enabling and non-enabling components aligned and oriented by a socket according to an embodiment of the present invention. Enabling components are those that thermally or mechanically secure an electronic package. In an embodiment, screws, nuts, bolts and heatsinks are typical enabling components. Non-enabling components are components other than enabling components that enable electrical (rather than physical as screws, nuts, etc.) function of the electronic package, which do not function to thermally or mechanically secure an electronic package. The term “non-enabling component” also includes the electronic package itself. In an embodiment, voltage regulator boards, power connector, and electronic packages are typical non-enabling components. Socket 100, which may contain electronic package 130 and may be adjoined to motherboard 110 may be affixed to chassis 120 by chassis stud 121, spring 122, fitting 123, and motherboard slot 113. In an embodiment, voltage regulator board 111 may be assembled next over socket 100, whereby voltage regulator board 111 may be oriented and aligned by a wall set and socket pin set featured on socket 100. Next, a backing plate 114 can be assembled over voltage regulator board 111. Next, voltage regulator heatsink 115 and electronic package heatsink 125 may be provided in the vertical assembly above the non-enabling components as illustrated in FIG. 1. In an embodiment, the voltage regulator heatsink 115 and electronic package heatsink 125 may be manufactured such that they join as one structural unit when assembled. The socket 100 may align and orient the package 130, the voltage regulator board 111, and/or other components in a selected alignment to socket 100 in a vertical arrangement, which may take up less space than if the components are arranged horizontally on motherboard 110.

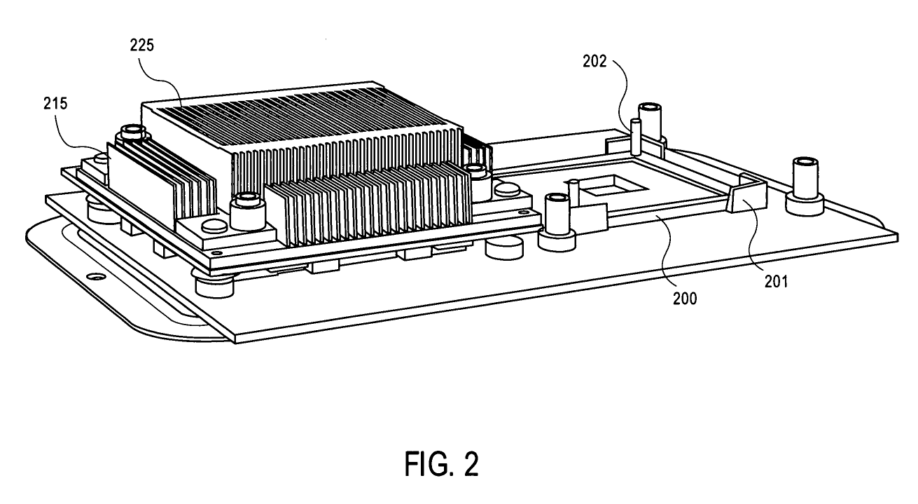

FIG. 2 illustrates a vertical assembly of components facilitated by socket 200 according to an embodiment of the present invention. FIG. 2 illustrates two sockets 200 side by side. Each socket 200 illustrated in FIG. 2 features wall set 201 and socket pin set 202 such that two vertical assemblies beside each other can be produced. In other embodiments, two vertical assemblies may be present in the same system, but not right beside each other. As illustrated in FIG. 2, voltage regulator heatsink 215 and electronic package heatsink 225 may comprise the top portion of the vertical assembly according to an embodiment of the present invention.

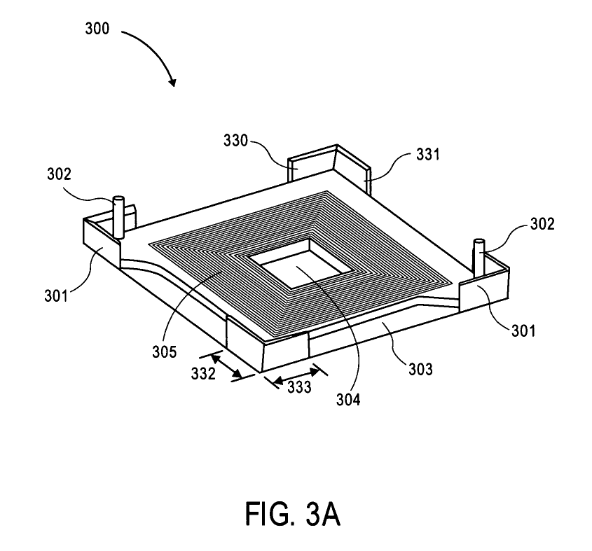

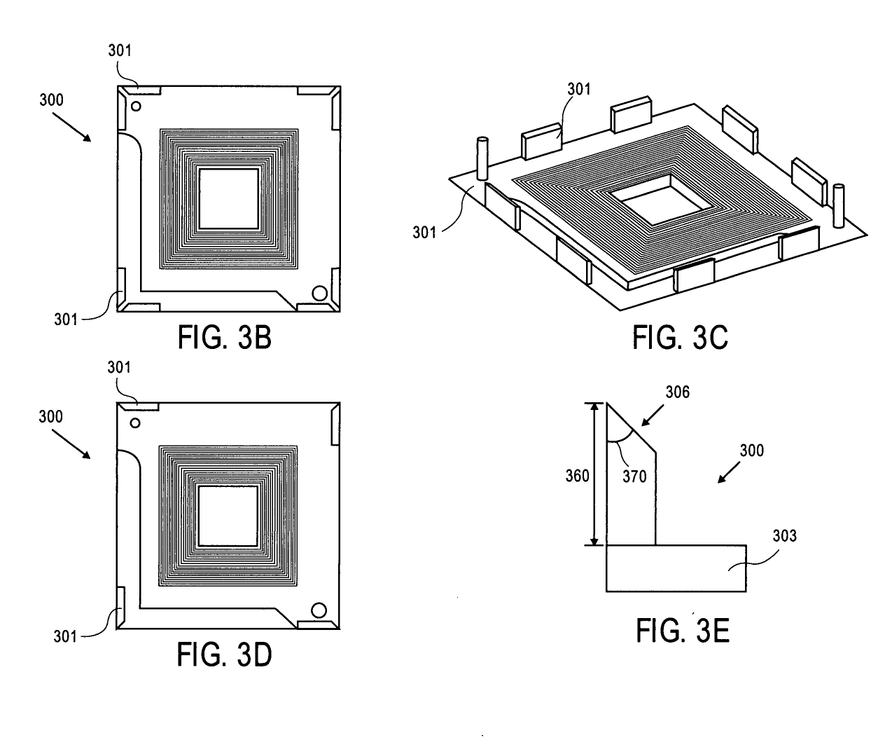

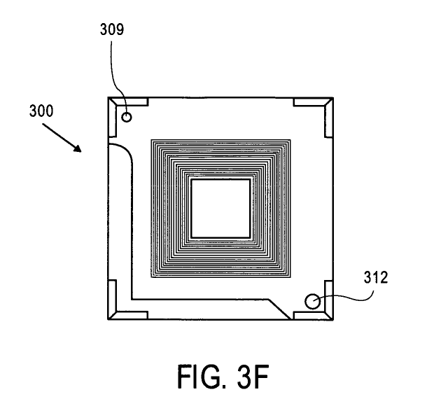

As illustrated in FIG. 3A, socket 300 may feature wall set 301 and socket pin set 302 to align and orient enabling and non-enabling components. In an embodiment, socket 300 may also comprise standard features such as base 303 and electronic package contacts 305. In an embodiment, base 303 may be a substantially planar portion of socket 300 from which wall set 301 and socket pin set 302 extends. In an embodiment, an opening 304 may be manufactured in base 303, which may allow electrical contact from a device (which may be a capacitor or other active or passive device) positioned in or below the opening 304 to an electronic package within the socket 300. In an embodiment, base 303 may comprise electronic package contacts 305, which provides electrical contact between socket 300 and an electronic package. Base 303 may comprise as many contacts as may be desired to provide electrical contact between socket 300 and an electronic package. In an embodiment as illustrated in FIG. 3A, 1248 electronic package contacts 305 may be included in the base 303. Embodiments of the present invention may be applicable for both Land Grid Array (LGA) sockets, Pin Grid Array (PGA) sockets, and/or any other suitable socket type. In an embodiment, socket 300 may be a LGA socket with 1248 electronic package contacts 305 as illustrated in FIG. 3A.

In an embodiment, wall set 301 may align enabling and non-enabling components of a vertical assembly. Wall set 301 may be manufactured such that it facilitates a substantially flush fit to a reciprocal element of a component assembled on socket 300. This substantially flush fit of a wall of wall set 301 to a reciprocal element of a component may align the component to socket 300. In an embodiment, wall set 301 and an assembled component may have a tolerance, which allows assembled components a limited range of motion in the x and y direction relative to the socket 300. The tolerance between wall set 301 and an assembled component may vary according to the component assembled on socket 300. In an embodiment, the tolerance between wall set 301 and an electronic package assembled on socket 300 may be 0.15 mm. In yet another embodiment, the tolerance between wall set 301 and an assembled voltage regulator power connector may be 0.3 mm, although other embodiments may have other tolerances.

Wall set 301 may have as many walls as may be suitable to provide alignment. In an embodiment as illustrated in FIG. 3A, wall set 301 may comprise eight individual walls. For example, wall 330 and wall 331, illustrated in FIG. 3A, may be considered two separate walls, even though as illustrated, they are a continuous piece of material. In an embodiment when wall set 301 comprises an even number of walls, wall set 301 may be positioned such that each wall abuts another wall as illustrated in FIG. 3A. In yet another embodiment, each wall of wall set 301 may be positioned such that each meets near a corner of base 303 without touching another wall, as illustrated in FIG. 3B. In yet another embodiment, the walls may be placed further from each other, as illustrated in FIG. 3C. In yet another embodiment, there may be single walls on each side of base 303 as illustrated in FIG. 3D. In yet other embodiments, the walls may be arranged differently. Each wall may be flat, to contact and align a flat surface of a component, curved, to contact and align a curved surface of a component, or another configuration. Wall set 301 may be located on the perimeter, center, or any suitable location of base 303. In an embodiment, walls of the wall set 301 may be positioned at the perimeter of base 303 to allow space for electronic package contacts 305 in the center of base 303.

In an embodiment, each wall of wall set 301 may extend a length along the base on a side of base 303 as illustrated in FIG. 3A. Length 332 and length 333 are lengths of two walls of wall set 301. In an embodiment, each of length 332 and length 333 is 7 mm. However, other embodiments may have different lengths such that length 332, length 333, and the lengths of other walls are not equal, and/or the lengths 332 and 333 may be different than 7 mm. In some embodiments as illustrated in FIG. 3E walls of wall set 301 may have a height 360 of about 3 mm, although in other embodiments, the walls may have differing, non-uniform heights 360, and/or the heights 360 may be greater or less than 3 mm. Wall set 301 may be manufactured with additional features to better facilitate component assembly to socket 300. In an embodiment, wall set 301 may feature a top tapered portion 306, as illustrated in FIG. 3E, to facilitate assembly of a voltage regulator. In an embodiment, the angle 370 of the tapered portion 306 may be about 60 degrees. In other embodiments, different taper angles may be used, or one or more (or even all) of the walls may lack a taper. In an embodiment, as a component is assembled on socket 300, initially there is less area of wall set 301 that comes into contact with the assembled component. Therefore, the lateral tolerance between tapered portion 306 and the assembled component may be greater in the top portion of wall set 301 where it is tapered than the remaining portion of wall set 301 to enhance ease of assembly. Wall set 301 may be comprised of metal, liquid crystal polymer, a different type of polymer, or any other suitable material or combination of materials known in the art. In an embodiment, wall set 301 may comprise a liquid crystal polymer material because of its characteristic moldable property. In an embodiment, wall set 301 may comprise liquid crystal polymers, which are easily molded into a desired configuration shape with desired features.

FIG. 3F is a top view that illustrates a socket 300 with a socket pin set 302 having a pin 309 with a smaller cross-sectional area and a pin 312 with a larger cross-sectional area. In an embodiment, socket pin set 302 may orient enabling and non-enabling components on socket 300. In an embodiment, socket pin set 302 may comprise a first socket pin 309 and a second pin 312, wherein the geometric configuration of a cross section of the first pin 309 may be different than the geometric configuration of a cross section of the second pin 312. “Geometric configuration” as used herein encompasses both size and shape of a cross section of a pin. For example, in an embodiment when the cross-sections of the first pin and the second pin have different areas but have the same shape (such as both being circular, but different size circles, as with pins 309 and 312 in FIG. 3F), they have a different geometric configuration. In an embodiment when the cross-sections of the first pin and the second pin have the same areas but have a different shape (such as one being circular and the other square), they have a different geometric configuration.

In an embodiment, the difference in geometric configuration between cross sections of the first pin and second pin may prevent incorrect assembly of components on socket 300. In an embodiment, the geometric configuration of the first pin may be cylindrical and the geometric configuration of the second pin may be hexagonal such that the first and second pin correspond to a cylindrical and hexagonal shaped openings, respectively, in a component to be assembled on socket 300, and may thus function to orient the component relative to the socket 300. In another embodiment, the first pin and the second pin may both have the same shaped cross section (such as circular) but different cross-sectional areas (e.g. one may be larger than the other) corresponding to smaller and larger holes in a component, and may thus function to orient the component relative to the socket 300. This is the case with pins 309 and 312 of FIG. 3F—the larger pin may be too large for an opening in a component and prevent the component from being incorrectly oriented relative to the socket 300. In an embodiment, the geometric configuration of each opening in an assembled component may correspond to a specific socket pin on socket 300.

The number of socket pins in socket pin set 302 and corresponding holes in components may vary from one to as many socket pins as are desired to orient components on socket 300. Socket pin set 302 may be positioned to any suitable location on base 303 such that orientation is accomplished. In an embodiment, socket pin set 302 may be positioned near the perimeter of base 303. Socket pin set 302 may be manufactured to a cylindrical, hexagonal, or any suitable cross-sectional shape and/or size such that socket pin set 302 fits in a corresponding opening in the components for orientation.

In an embodiment, socket pin set 302 may be manufactured to a cylindrical shape with tapered ends to facilitate component assembly into socket 300. The height of socket pin set 302 may contribute to adequate assembly of components on socket 300. In an embodiment, each socket pin in socket pin set 302 may have a height of 14.6 mm, approximately 11 mm above wall set 301, although other heights may be used, and each pin of socket pin set 302 need not be the same height. Socket pin set 302 may comprise any suitable material. In an embodiment, socket pin set 302 may comprise stainless steel. Socket pin set 302 may serve other functions in addition to orientation. In an embodiment, socket pin set 302 may provide rough alignment of components assembled on socket 300.

In an embodiment, socket pin set 302 may comprise two pins which are positioned apart such that a given amount of tolerance is present between the pins and an assembled component, without compromising socket pin set's 302 orientation function. In an embodiment when socket pin set 302 provides rough alignment of assembled components on socket 300, there may be a tolerance between socket pin set 302 and an assembled component. This tolerance may be greater than the tolerance between wall set 301 and the assembled component. In an embodiment, the range of motion in the x and y direction granted by the tolerance between socket pin set 302 and an assembled component may be greater than the range of motion in the x and y direction provided by wall set 301 and the assembled component. In an embodiment, the tolerance between socket pin set 302 and an electronic package may be about 0.25 mm, although in other embodiments, the tolerance may be different.

Enabling and non-enabling components may be assembled on a socket of the present invention by any suitable method known in the art. For example, components may be individually assembled on a socket of the present invention or individual components may be sub-assembled and subsequently stacked on a socket of the present invention to form a vertical assembly.

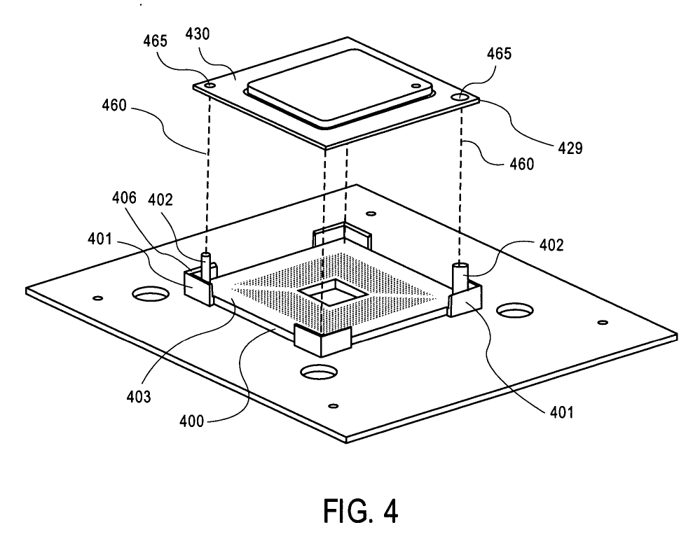

FIG. 4 is an exploded view that illustrates how an electronic package may be assembled onto socket 400 and aligned and oriented to socket 400 by wall set 401 and socket pin set 402, according to one embodiment of the present invention. In the illustrated embodiment, socket pin set 402 fits in the electronic package opening set 465 as illustrated in FIG. 4. Dotted lines 460 are incorporated in FIG. 4 to illustrate how electronic package opening set 465 of electronic package 430 corresponds with socket pin set 402 to facilitate alignment. In an embodiment, electronic package 430 may be assembled vertically on socket 400 with the substrate portion 429 of electronic package 430 facing base 403. Electronic package opening set 465 comes into contact with socket pin set 402 such that assembly is allowed when the socket pin of socket pin set 402 meets the corresponding electronic package opening of electronic package opening set 465. In an embodiment, each opening of electronic package opening set 465 is manufactured such that it is equal or greater than the corresponding socket pins of socket pin set 402 but one opening may be smaller than one of the larger pins so it can not be inserted incorrectly as illustrated in FIG. 4. In an embodiment, the borders of electronic package 430 may come into contact with wall set 401. In an embodiment when wall set 401 comprises a top tapered portion 406, assembly may be enhanced in the top portion of wall set 401 due to the increased tolerance between the assembled component and wall set 401. In an embodiment, electronic package 430 may be fully assembled on socket 400 when the substrate portion 429 of electronic package 430 is flush with base 403.

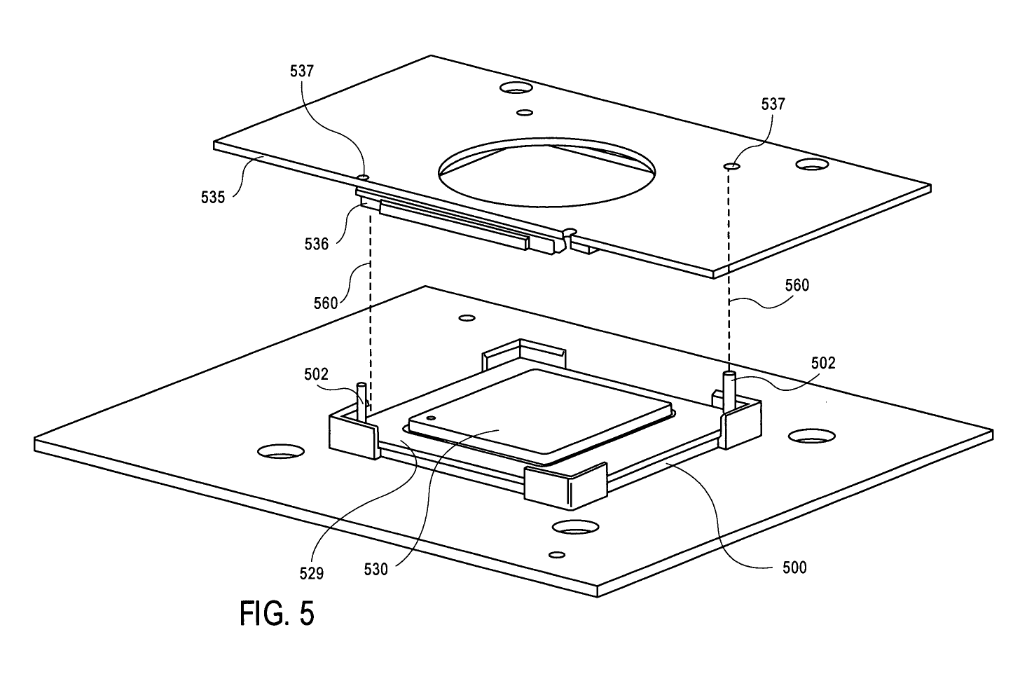

FIG. 5 is a perspective view of a voltage regulator board 535 with adjoining power connectors 536 aligned and oriented to a socket according to an embodiment of the present invention. As illustrated, voltage regulator board 535 comprises power connectors 536, which channels power from voltage regulator board 535 to electronic package 530. In an embodiment, voltage regulator board may be oriented to electronic package 530 by socket pin set 502. Voltage regulator opening set 537 may be manufactured to facilitate orientation of voltage regulator board 535 to socket 500. In an embodiment, each opening of voltage regulator opening set 537 may be manufactured such that it is equal or greater than the corresponding socket pin of socket pin set 502 but one opening may be smaller than one of the larger pins so it can not be inserted incorrectly as illustrated in FIG. 5. Dotted lines 560 are incorporated in FIG. 5 to illustrate how voltage regulator opening set 537 of voltage regulator 535 corresponds with socket pin set 502 to facilitate orientation. In an embodiment when electronic package 530 has been assembled to socket 500, voltage regulator board 535 may be assembled vertically to socket 500 with power connectors 536 facing electronic package 530. In an embodiment, power connectors 530 may come into contact with wall set 501. In an embodiment, the shape of power connectors 536 may be the reciprocal shape of wall set 501, such that voltage regulator 535 fits substantially flush with wall set 501 upon assembly. By having such a reciprocal shape that sits substantially flush with the wall set, the power connectors 536 in conjunction with the wall set 501 may align the voltage regulator 535. In an embodiment, voltage regulator 535 may be fully assembled on socket 500 when power connectors 536 are flush with the substrate portion 529 of electronic package 530.

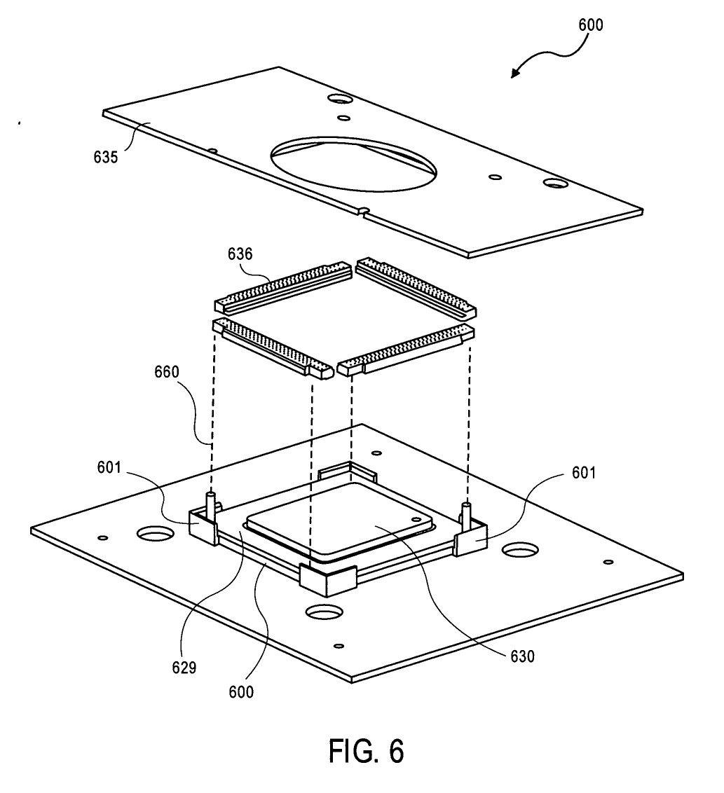

FIG. 6 is a perspective view of power connectors 636 aligned to socket 600 according to an embodiment of the present invention. FIG. 6 illustrates the alignment of power connectors 636 disassembled from voltage regulator board 635. In an embodiment, voltage regulator board 635 may be aligned to electronic package 630 by power connectors 636. Dotted lines 660 are incorporated in FIG. 6 to illustrate how power connectors 636 correspond with wall set 601 to facilitate alignment. In an embodiment, power connectors 636 may come into contact with wall set 601. In an embodiment, the shape of power connectors 636 may be the reciprocal shape of wall set 601, such that voltage regulator 635 fits substantially flush with wall set 601 upon assembly. In an embodiment, voltage regulator 635 may be fully assembled on socket 600 when power connectors 635 are substantially flush with the substrate portion 629 of electronic package 630. By having such a reciprocal shape that sits substantially flush with wall set 601, the power connectors 636 in conjunction with wall set 601 may align the voltage regulator 635. By having such a reciprocal shape that sits flush with the wall set, the power connectors 636 in conjunction with wall set 601 may align voltage regulator 635.

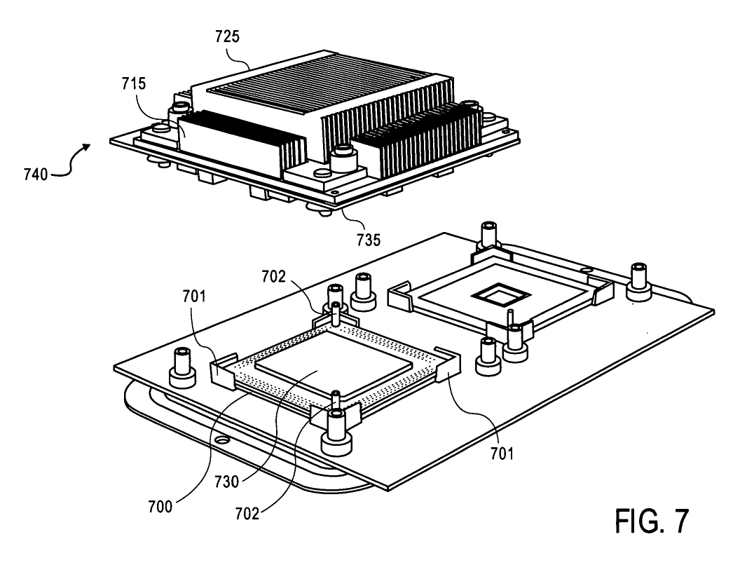

In an embodiment as illustrated in FIG. 7, a subassembly 740 may be formed and subsequently assembled over electronic package 730, and then postioned within socket 700 as a subassembly 740, rather than separately positioning the individual parts of the subassembly 740. As illustrated, subassembly 740 is aligned and oriented by socket 700 features, wall set 701 and socket pin set 702, respectively. In an embodiment, subassembly 740 may comprise of voltage regulator board 735, voltage regulator heatsink 715, and electronic package heatsink 725.

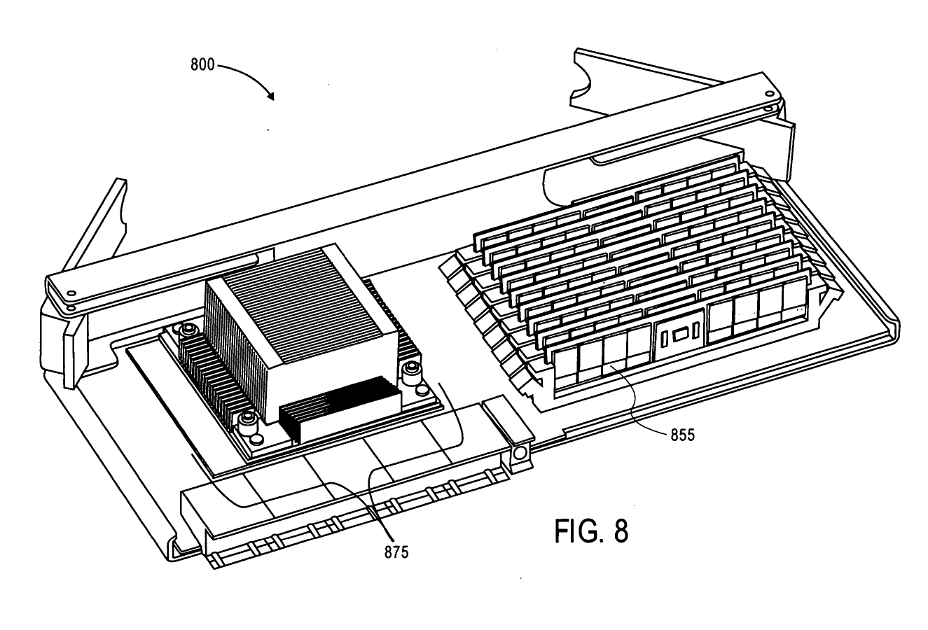

FIG. 8 illustrates a vertical assembly 875 of enabling and non-enabling components on a socket of the present invention in a computing system 800 over an assembly where components, such as an electronic package and voltage regulator are placed side-by-side on the motherboard. Computing system 800 comprises standard features such as but not limited to memory 855 as illustrated. Vertical assembly 875 can save considerable lateral space in computing system 800. The amount of lateral space saved can range up to the composite length of the power connector and voltage board regulator.

1. A socket for an electronic package comprising:
a base having a surface;
a set of guideways connected to said base to align a first non-enabling component and a second non-enabling component, wherein said set of guideways comprises a first guideway abutting a second guideway at the perimeter of said base and wherein each of said first guideway and said second guideway has a tapered top portion; and
a socket pin set extending above the surface of said base to orient said first non-enabling component and said second non-enabling component.

2. (canceled)

3. The socket of clam 2, wherein said first guideway is approximately 90 degrees to said second wall.

4. The socket of claim 1, wherein said socket pin set has a first pin and a second pin.

5. The socket of claim 4, wherein said first pin has a cross section with a first geometric configuration and said second pin has a cross section with a second geometric configuration.

6-22. (canceled)

23. The socket of claim 1 further comprising a guideway at all corners of said base.

24. The socket of claim 5, wherein said first geometric configuration and said second geometric configuration are the same shape.

25. The socket of claim 5, wherein the shape of said first geometric configuration is circular and the shape of said second geometric configuration is substantially square.

26. The socket of claim 5, wherein the cross-sectional area of said first pin is larger than the cross sectional area of said second pin.

27. The socket of claim 5, wherein said first pin and said second pin inserts into corresponding holes in said first non-enabling component and said second non-enabling component.

28. The socket of claim 5, wherein said first pin and said second pin has a shape that is selected from the group consisting of cylindrical and hexagonal.
